(19) United States
(12) Patent Application Publication
(10) Pub. No.: US 2026/0066867 A1
(43) Pub. Date: Mar. 5, 2026

(54) MULTILAYER COMMON MODE FILTER

(71) Applicant: AMOTECH CO., LTD., Incheon (KR)

(72) Inventor: Byungguk LIM, Incheon (KR)

(73) Assignee: AMOTECH CO., LTD., Incheon (KR)

(21) Appl. No.: 19/107,143

(22) PCT Filed: Aug. 21, 2023
(86) PCT No.: PCT/KR2023/012321

§ 371 Date: Feb. 27, 2025

(30) Foreign Application Priority Data
Aug. 30, 2022 (KR) 10-2022-0109047

(51) Int. Cl. H03H 7/01; H01F 27/28; H01G 4/30

(52) U.S. Cl. CPC H03H 7/1741; H01F 27/2804; H01G 4/30; H03H 7/0115; H01F 2027/2809

(57) ABSTRACT

A multilayer common mode filter of the present disclosure has a filter stack configured by stacking, underneath a coil stack comprising a plurality of coils configuring mutually different channels, a stack provided with a capacitor pattern, a floating pattern, an inductor pattern, and a ground pattern, wherein resonance frequency characteristics may be changed according to the inductor pattern.

### TECHNICAL FIELD

The present disclosure relates to a multilayer common mode filter that allows signal current in a differential mode to pass through and removes noise current in a common mode in an electronic device to which a high-speed signal line is applied.

### BACKGROUND ART

Generally, mobile terminals adopt the Mobile Industry Processor Interface (MIPI) D-PHY standard as a digital data transmission standard. The MIPI D-PHY standard is a digital data transmission standard that connects a main circuit of a mobile terminal to a display or camera, and refers to a method of transmitting data using a differential signal with two transmission lines.

With the rapid increase in the volume of data transmitted and received within mobile terminals, a transmission method capable of transmitting and receiving data at a higher speed than the MIPI D-PHY standard is required for mobile terminals.

Accordingly, recent research in the mobile terminal industry has been conducted on applying the MIPI C-PHY standard to mobile terminals. The MIPIC-PHY standard employs three transmission lines, transmitting different voltages to the respective transmission lines from a transmitting side and performing differential output on a receiving side by taking differences between the lines.

The contents described in the Background Art are to aid in understanding the background of the disclosure, and may include contents that are not related to disclosed prior technology.

### SUMMARY OF INVENTION

### Technical Problem

The present disclosure is proposed in consideration of the circumstances, and an object of the present disclosure is to provide a multilayer common mode filter in which a stack including a capacitor pattern, a floating pattern, an inductor pattern, and a ground pattern is disposed under a filter stack, thereby enabling control of characteristics such as a resonance point (resonant frequency) and cutoff.

### Solution to Problem

To achieve the above object, a multilayer common mode filter according to an embodiment of the present disclosure may include a first stack provided with a first coil pattern, a second coil pattern, and a third coil pattern, a second stack provided with a fourth coil pattern, a fifth coil pattern, and a sixth coil pattern, and disposed under the first stack, and a third stack disposed under the second stack. The third stack may include a plurality of capacitor patterns disposed under the second stack, a floating pattern disposed under the plurality of capacitor patterns, and configured to form additional capacitance by overlapping the plurality of capacitor patterns, a ground pattern disposed under the floating pattern, and an inductor pattern disposed between the floating pattern and the ground pattern. A first end of the inductor pattern may be connected to the floating pattern, and a second end of the inductor pattern may be connected to the ground pattern.

The third stack may include a ninth sheet, a plurality of capacitor patterns placed on a first surface of the ninth sheet and spaced apart from each other, a tenth sheet disposed under the ninth sheet, and a floating pattern placed on a first surface of the tenth sheet, and forming a plurality of overlapping areas by overlapping the plurality of capacitor patterns, the floating pattern being configured to form additional capacitance in the plurality of overlapping regions.

The third stack may further include the ground pattern disposed under the tenth sheet, and the inductor pattern interposed between the tenth sheet and the ground pattern, and including a first end connected to the floating pattern, and a second end connected to the ground pattern.

The third stack may further include an eleventh sheet interposed between the tenth sheet and the ground pattern, and a twelfth sheet interposed between the eleventh sheet and the ground pattern. The inductor pattern may include a first inductor pattern placed on a first surface of the eleventh sheet, and including a first end connected to the floating pattern through a via hole passing through the tenth sheet, and a second end spaced apart from the first end, and a second inductor pattern placed on a first surface of the twelfth sheet, and including a first end connected to the ground pattern, and a second end connected to the second end of the first inductor pattern through a via hole passing through the eleventh sheet.

The multilayer common mode filter may further include a first magnetic sheet disposed over the first stack, and a second magnetic sheet interposed between the second stack and the third stack. The multilayer common mode filter may further include a third magnetic sheet disposed under the third stack.

A filter stack formed by stacking the first stack, the second stack, and the third stack may have a first resonant frequency, and a second resonant frequency higher than the first resonant frequency. The second resonant frequency may shift to a higher frequency as a length of the inductor pattern increases.

### Advantageous Effects of Invention

According to the present disclosure, a multilayer common mode filter has an effect of allowing a distance (spacing) between coil patterns forming each channel to be kept constant, thereby enabling resistance and inductance of the coil patterns forming each channel to remain uniform.

Furthermore, the multilayer common mode filter has an effect of minimizing changes in inductance characteristics and common mode attenuation characteristics of the coil patterns by disposing terminal patterns for connection with external electrodes in uppermost and lowermost portions of a filter stack.

In addition, the multilayer common mode filter has an effect of expanding an attenuation band by forming an additional notch in common mode attenuation characteristics through placement of a capacitor pattern and a floating pattern below a coil stack.

Additionally, the multilayer common mode filter has an effect of achieving broadband characteristics by forming an additional pole (i.e., additional capacitance) through the capacitor pattern and the floating pattern, along with a pole formed by the coil patterns of an electrode stack.

Furthermore, the multilayer common mode filter has an effect of minimizing variations in the inductance characteristics of the coil patterns by forming a constant distance (spacing) between the channels.

In addition, the multilayer common mode filter has an effect of enhancing magnetic coupling (i.e., electromagnetic coupling) among first to third coils and minimizing the degradation of a differential signal.

Additionally, the multilayer common mode filter has an effect of simplifying a manufacturing process because the electrode stack can be formed by stacking sheets in which two or fewer via holes are formed.

That is, in the multilayer common mode filter, the terminal patterns are disposed in uppermost and lowermost portions of the electrode stack, a second coil pattern and a third coil pattern of a second channel are placed between a first coil pattern and a sixth coil pattern of a first channel, and a fourth coil pattern and a fifth coil pattern of a third channel are placed between the third coil pattern and the sixth coil pattern. Accordingly, the number of via holes required to connect the coil patterns may be minimized, and two or fewer via holes are formed in each sheet.

Furthermore, the multilayer common mode filter has an effect of increasing capacitance, without adding an electrode layer that includes a coil pattern or increasing the area of the coil pattern, thereby achieving a greater capacitance than prior multilayer common mode filters within the same size.

In addition, the multilayer common mode filter has an effect of changing characteristics of a second resonant frequency by adjusting the length of an inductor pattern.

Furthermore, the multilayer common mode filter has an effect of readily adjusting and controlling the second resonant frequency because a short path circuit formed of the floating pattern, the inductor pattern, and a ground pattern is configured through a third stack disposed under the coil stack.

In addition, the multilayer common mode filter has an effect of enabling adjustment of a distance between a first resonant frequency and a second resonant frequency by placing or removing a magnetic sheet in or from the lowermost portion of the filter stack.

### BRIEF DESCRIPTION OF DRAWINGS

FIG. 1 is a perspective view of a multilayer common mode filter according to an embodiment of the present disclosure.

FIG. 2 is an exploded perspective view for describing a filter stack in FIG. 1.

FIG. 3 is an exploded perspective view for describing a first stack in FIG. 2.

FIG. 4 is a diagram for describing a first sheet in FIG. 3.

FIG. 5 is a diagram for describing a second sheet in FIG. 3.

FIG. 6 is a diagram for describing a third sheet in FIG. 3.

FIG. 7 is a diagram for describing a fourth sheet in FIG. 3.

FIG. 8 is an exploded perspective view for describing a second stack in FIG. 2.

FIG. 9 is a diagram for describing a fifth sheet in FIG. 8.

FIG. 10 is a diagram for describing a sixth sheet in FIG. 8.

FIG. 11 is a diagram for describing a seventh sheet in FIG. 8.

FIG. 12 is a diagram for describing an eighth sheet in FIG. 8.

FIG. 13 is a sectional view showing a vertical cross-section of a coil stack in FIG. 2.

FIG. 14 is an exploded perspective view for describing a third stack in FIG. 2.

FIG. 15 is a diagram for describing a ninth sheet in FIG. 14.

FIG. 16 is a diagram for describing a tenth sheet in FIG. 14.

FIG. 17 is a diagram for describing an eleventh sheet in FIG. 14.

FIGS. 18 and 19 are diagrams for describing a twelfth sheet in FIG. 14.

FIG. 20 is a diagram for describing a thirteenth sheet in FIG. 14.

FIG. 21 is a diagram illustrating an equivalent circuit of the multilayer common mode filter according to an embodiment of the present disclosure.

FIGS. 22 to 24 are diagrams for comparatively explaining the characteristics of a multilayer common mode filter depending on changes in the length (area) of an inductor pattern.

FIGS. 25 and 26 are exploded perspective views for explaining modified examples of the multilayer common mode filter according to an embodiment of the present disclosure.

FIGS. 27 and 28 are diagrams for comparatively explaining the characteristics of the multilayer common mode filter depending on the presence or absence of a third magnetic sheet shown in FIG. 26.

FIGS. 29 to 31 are diagrams for comparatively explaining the characteristics of the multilayer common mode filter according to an embodiment of the present disclosure and a prior multilayer common mode filter.

### DESCRIPTION OF EMBODIMENTS

Hereinafter, embodiments of the present disclosure will be described in detail with reference to the attached drawings.

Embodiments are provided to explain the present disclosure more fully to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of embodiments, when it is described that each layer (film), area, pattern, or structure is formed “on” or “under” each substrate, layer (film), area, pad, or pattern, this includes both expressions, including that a layer is formed on another layer “directly” or “with an additional layer interposed between the two layers (indirectly)”. Furthermore, the criterion for “on” or “under” of each layer is based on the drawings.

The drawings are provided solely to aid in understanding the spirit of the present disclosure and should not be interpreted as limiting the scope of the present disclosure. Furthermore, in the drawings, relative thickness, length, or size may be exaggerated for convenience and clarity of description.

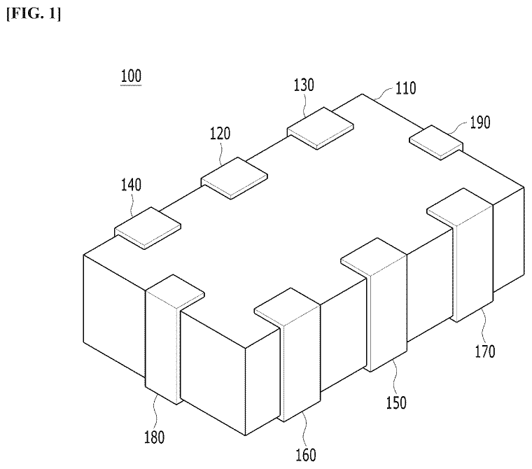

Referring to FIG. 1, a multilayer common mode filter 100 according to an embodiment of the present disclosure includes a filter stack 110, a first external electrode 120, a second external electrode 130, a third external electrode 140, a fourth external electrode 150, a fifth external electrode 160, a sixth external electrode 170, a seventh external electrode 180, and an eighth external electrode 190. Hereinafter, the multilayer common mode filter 100 operating as a three-channel C-PHY common mode filter will be described as an example.

The filter stack 110 is a stack in which sheets, on which six coil patterns forming three channels, a capacitor pattern for adjusting characteristics such as a resonant frequency, a floating pattern 522, inductor patterns 532 and 542, and aground pattern 552 are arranged, are stacked. The multilayer common mode filter 100 adjusts resonance point (resonant frequency) shift, cutoff characteristics, and the like through the capacitor pattern and a floating pattern 522 that form capacitance, inductor patterns 532 and 542 constituting inductance, and aground pattern 552 forming a ground.

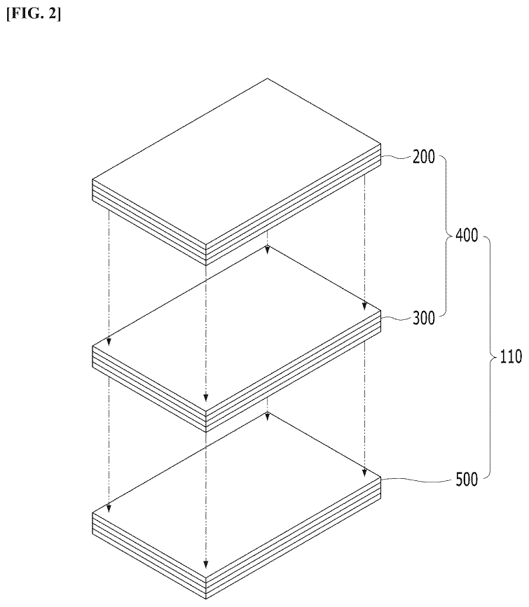

Referring to FIG. 2, the filter stack 110 includes a first stack 200, a second stack 300 disposed under the first stack 200, and a third stack 500 disposed under the second stack 300.

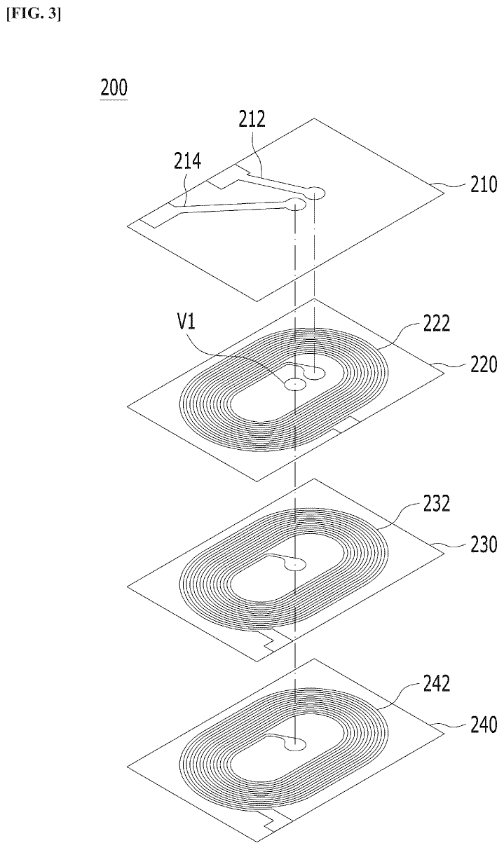

The first stack 200 is formed by stacking a plurality of sheets on which metal patterns are formed. For example, referring to FIG. 3, the first stack 200 includes a first sheet 210, a second sheet 220 disposed under the first sheet 210, a third sheet 230 disposed under the second sheet 220, and a fourth sheet 240 disposed under the third sheet 230.

Here, metal patterns corresponding to terminal patterns 212 and 214 are formed in the first sheet 210, and metal patterns corresponding to coil patterns 222, 232, and 242 are formed in the second to fourth sheets 220 to 240.

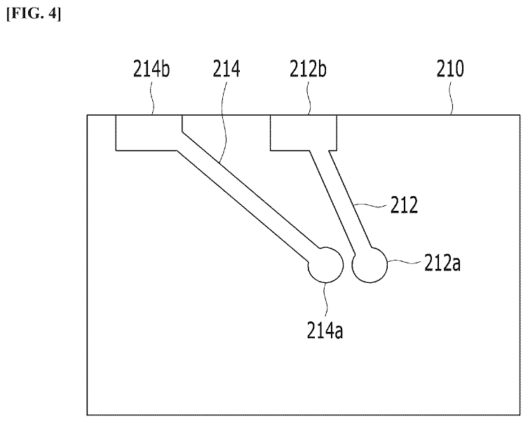

Referring to FIG. 4, a first terminal pattern 212 and a second terminal pattern 214 for connecting coil patterns of a first electrode layer to external electrodes are formed on the first sheet 210.

The first terminal pattern 212 is placed on an upper surface of the first sheet 210. A first end 212a of the first terminal pattern 212 is disposed adjacent to a center of the first sheet 210.

A second end 212b of the first terminal pattern 212 is disposed to be aligned with a first side of the first sheet 210. Accordingly, the second end 212b of the first terminal pattern 212 is exposed to a first side surface of the filter stack 110, and connected to the first external electrode 120.

The second terminal pattern 214 is placed on the upper surface of the first sheet 210 so as to be spaced apart from the first terminal pattern 212. A first end 214a of the second terminal pattern 214 is disposed adjacent to the center of the first sheet 210. The first end 214a of the second terminal pattern 214 is spaced apart from the first end 212a of the first terminal pattern 212 by a predetermined distance.

A second end 214b of the second terminal pattern 214 is disposed to be aligned with the first side of the first sheet 214. Accordingly, the second end 214b of the second terminal pattern 214 is spaced apart from the second end 212b of the first terminal pattern 212 by a predetermined distance, and is exposed to the first side surface of the filter stack 110, and connected to the third external electrode 140.

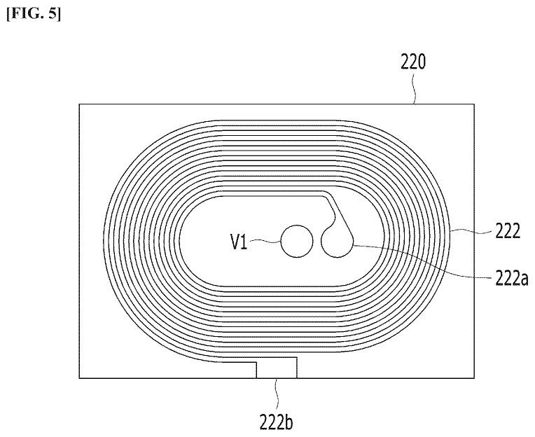

Referring to FIG. 5, the second sheet 220 is disposed under the first sheet 210. A first via hole V1 and a first coil pattern 221 that forms a first channel are disposed in the second sheet 220.

The first coil pattern 222 is placed on an upper surface of the second sheet 220. The first coil pattern 222 is wound multiple times on the upper surface of the second sheet 220, thus forming a first loop. The first coil pattern 222 is wound multiple times around a virtual winding axis passing through a center of the second sheet 220 to form the first loop.

A first end 222a of the first coil pattern 222 is disposed in an inner peripheral region of the first loop, and positioned adjacent to the center of the second sheet 220. The first end 222a of the first coil pattern 222 is connected to the first end 212a of the first terminal pattern 212 through a via hole.

A second end 222b of the first coil pattern 222 is disposed in an outer peripheral region of the first loop, and disposed to be aligned with a second side of the second sheet 220. Accordingly, the second end 222b of the first coil pattern 222 is exposed to a second side surface of the filter stack 110, and connected to the fourth external electrode 150.

The first via hole V1 is disposed so as to be adjacent to the center of the second sheet 220 and to be spaced apart from the first end 222a of the first coil pattern 222. The first via hole V1 is formed to penetrate through the second sheet 220. An upper portion of the first via hole V1 is connected to the second terminal pattern 214. A lower portion of the first via hole is connected to the coil pattern that is formed in the third sheet 230, which will be described below.

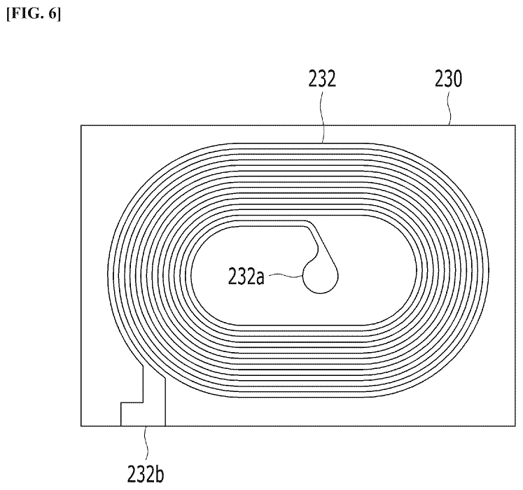

Referring to FIG. 6, the third sheet 230 is disposed under the second sheet 220. A second coil pattern 232 that forms a second channel is disposed in the third sheet 230.

The second coil pattern 232 is placed on an upper surface of the third sheet 230. The second coil pattern 232 is wound multiple times on the upper surface of the third sheet 230, thus forming a second loop. The second coil pattern 232 is wound multiple times around a virtual winding axis passing through a center of the third sheet 230 to form the second loop.

A first end 232a of the second coil pattern 232 is disposed in an inner peripheral region of the second loop, and positioned adjacent to the center of the third sheet 230. The first end 232a of the second coil pattern 232 is connected to the first end 214a of the second terminal pattern 214 through the first via hole V1 of the second sheet 220.

A second end 232b of the second coil pattern 232 is disposed in an outer peripheral region of the second loop, and disposed to be aligned with a second side of the third sheet 230. The second end 232b of the second coil pattern 232 is disposed to be spaced apart from the second end 222b of the first coil pattern 222 by a predetermined distance, and is exposed to the second side surface of the filter stack 110, and connected to the fifth external electrode 160.

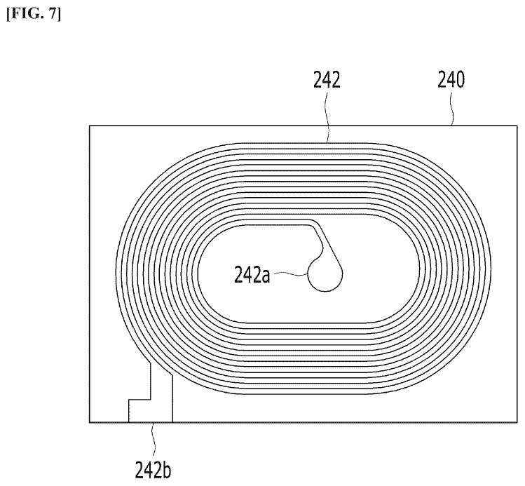

Referring to FIG. 7, the fourth sheet 240 is disposed under the third sheet 230. A third coil pattern 242 that forms the second channel along with the second coil pattern 232 is disposed in the fourth sheet 240.

The third coil pattern 242 is placed on an upper surface of the fourth sheet 240. The third coil pattern 242 is wound multiple times on the upper surface of the fourth sheet 240, thus forming a third loop. The third coil pattern 242 is wound multiple times around a virtual winding axis passing through the center of the fourth sheet 240 to form the third loop.

A first end 242a of the third coil pattern 242 is disposed in an inner peripheral region of the third loop, and positioned adjacent to a center of the fourth sheet 240. The first end 242a of the third coil pattern 242 is connected to the first end 232a of the second coil pattern 232 through a via hole, and connected to the first end 214a of the second terminal pattern 214 through the first via hole V1 of the second sheet 220.

A second end 242b of the third coil pattern 242 is disposed in an outer peripheral region of the third loop, and disposed to be aligned with a second side of the fourth sheet 240. Accordingly, the second end 242b of the third coil pattern 242 is disposed to be spaced apart from the second end 222b of the first coil pattern 222 by a predetermined distance.

The second end 242b of the third coil pattern 242 is disposed to be aligned with the second end 232b of the second coil pattern 232, and is exposed to the second side surface of the filter stack 110 to be connected to the fifth external electrode 160 along with the second end 232b of the second coil pattern 232.

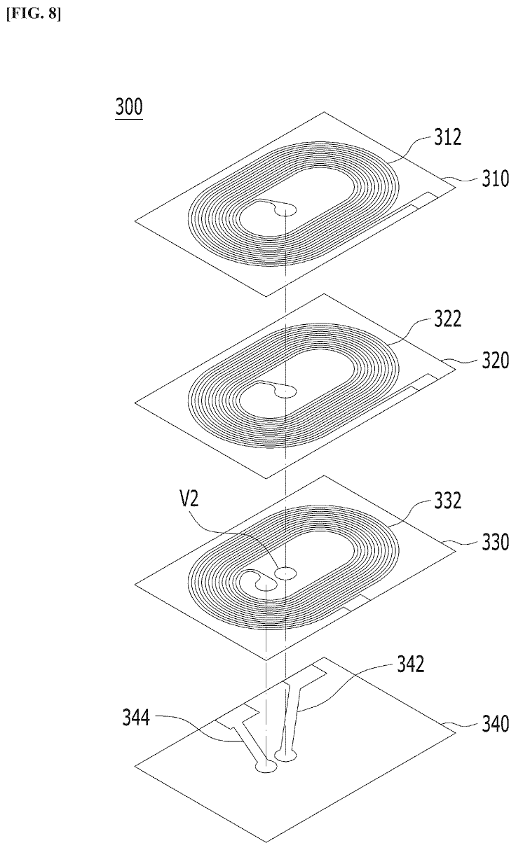

The second stack 300 is disposed under the first stack 200, and formed by stacking a plurality of sheets on which metal patterns are formed. For example, referring to FIG. 8, the second stack 300 includes a fifth sheet 310, a sixth sheet 320 disposed under the fifth sheet 310, a seventh sheet 330 disposed under the sixth sheet 320, and an eighth sheet 340 disposed under the seventh sheet 330. Here, metal patterns corresponding to coil patterns 312, 322, and 332 are formed in the fifth to seventh sheets 310 to 330, and metal patterns corresponding to terminal patterns 342 and 344 are formed in the eighth sheet 340.

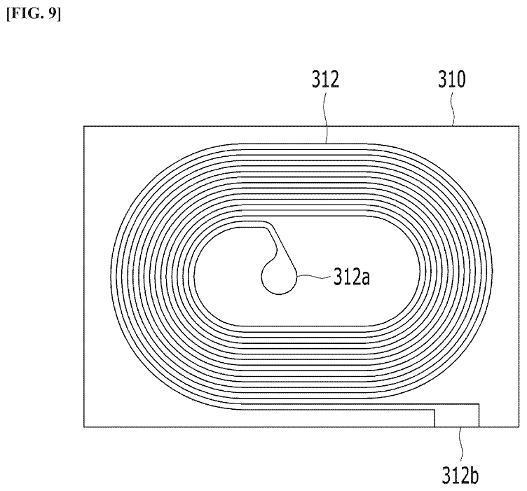

Referring to FIG. 9, the fifth sheet 310 is disposed under the fourth sheet 240, and a fourth coil pattern 312 that forms a third channel is disposed in the fifth sheet 310.

The fourth coil pattern 312 is placed on an upper surface of the fifth sheet 310. The fourth coil pattern 312 is wound multiple times on the upper surface of the fifth sheet 310, thus forming a fourth loop. The fourth coil pattern 312 is wound multiple times around a virtual winding axis passing through a center of the fifth sheet 310 to form the fourth loop.

A first end 312a of the fourth coil pattern 312 is disposed in an inner peripheral region of the fourth loop, and positioned adjacent to the center of the fifth sheet 310. The first end 312a of the fourth coil pattern 312 is connected to a first end 322a of a fifth coil pattern 322, which will be described below, through a via hole.

A second end 312b of the fourth coil pattern 312 is disposed in an outer peripheral region of the fourth loop, and disposed to be aligned with a second side of the fifth sheet 310. The second end 312b of the fourth coil pattern 312 is exposed to the second side surface of the filter stack 110, and connected to the sixth external electrode 170.

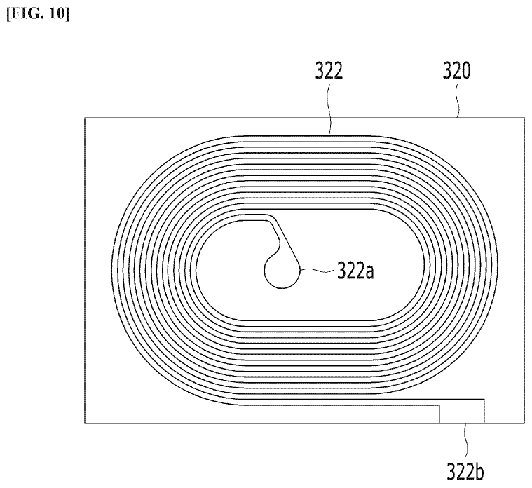

Referring to FIG. 10, the sixth sheet 320 is disposed under the fifth sheet 310. The fifth coil pattern 322 that forms the third channel along with the fourth coil pattern 312 is disposed in the sixth sheet 320.

The fifth coil pattern 322 is placed on an upper surface of the sixth sheet 320. The fifth coil pattern 322 is wound multiple times on the upper surface of the sixth sheet 320, thus forming a fifth loop. The fifth coil pattern 322 is wound multiple times around a virtual winding axis passing through a center of the sixth sheet 320 to form the fifth loop.

A first end 322a of the fifth coil pattern 322 is disposed in an inner peripheral region of the fifth loop, and positioned adjacent to the center of the sixth sheet 320. The first end 322a of the fifth coil pattern 322 is connected to the first end 312a of the fourth coil pattern 312 through a via hole.

A second end 322b of the fifth coil pattern 322 is disposed in an outer peripheral region of the fifth loop, and disposed to be aligned with a second side of the sixth sheet 320. The second end 322b of the fifth coil pattern 322 is aligned with the second end 312b of the fourth coil pattern 312, and is exposed to the second side surface of the filter stack 110 to be connected to the sixth external electrode 170 along with the second end 312b of the fourth coil pattern 312.

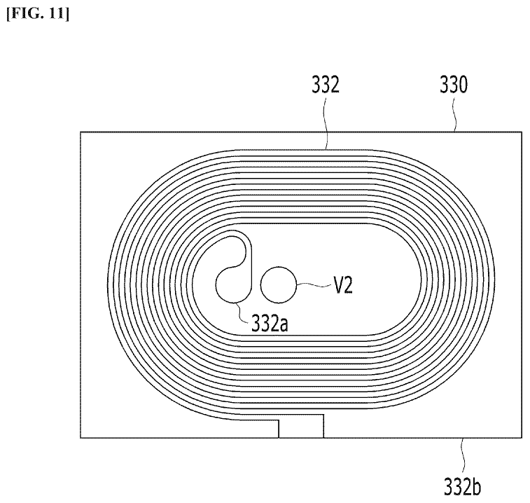

Referring to FIG. 11, the seventh sheet 330 is disposed under the sixth sheet 320. A second via hole V2 and a sixth coil pattern 332 that forms the first channel along with the first coil pattern 222 of the first stack 200 are formed in the seventh sheet 330.

The sixth coil pattern 332 is placed on an upper surface of the seventh sheet 330. The sixth coil pattern 332 is wound multiple times on the upper surface of the seventh sheet 330, thus forming a sixth loop. The sixth coil pattern 332 is wound multiple times around a virtual winding axis passing through a center of the seventh sheet 330 to form the sixth loop.

A first end 332a of the sixth coil pattern 332 is disposed in an inner peripheral region of the sixth loop, and positioned adjacent to the center of the seventh sheet 330.

A second end 332b of the sixth coil pattern 332 is disposed in an outer peripheral region of the sixth loop, and disposed to be aligned with a second side of the seventh sheet 330. The second end 332b of the sixth coil pattern 332 is disposed to be spaced apart from the second end 312b of the fourth coil pattern 312 and the second end 322b of the fifth coil pattern 322 by predetermined distances, and is exposed to the second side surface of the filter stack 110 to be connected to the fourth external electrode 150.

The second via hole V2 is disposed so as to be adjacent to the center of the seventh sheet 330 and to be spaced apart from the first end 332a of the sixth coil pattern 332. The second via hole V2 is formed to penetrate through the seventh sheet 330. An upper portion of the second via hole V2 is connected to the first end 312a of the fourth coil pattern 312 and the first end 322a of the fifth coil pattern 322. A lower portion of the second via hole V2 is connected to a third terminal pattern 342 formed in the eighth sheet 340, which will be described below.

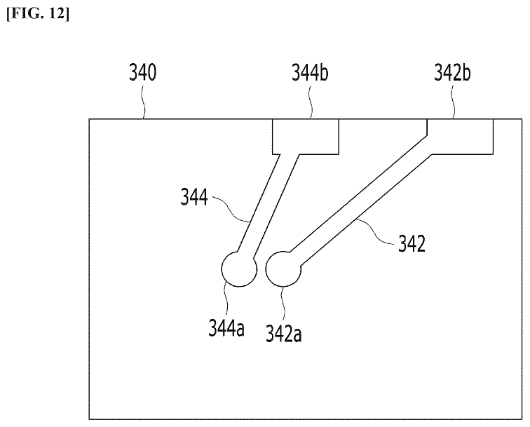

Referring to FIG. 12, the third terminal pattern 342 and a fourth terminal pattern 344 for connecting coil patterns of a second electrode layer to external electrodes are formed in the eighth sheet 340.

The third terminal pattern 342 is placed on an upper surface of the eighth sheet 340. A first end 342a of the third terminal pattern 342 is disposed adjacent to a center of the eighth sheet 340. The first end 342a of the third terminal pattern 342 is connected to the first end 312a of the fourth coil pattern 312 and the first end 322a of the fifth coil pattern 322 through the second via hole V2.

A second end 342b of the third terminal pattern 342 is disposed to be aligned with a first side of the eighth sheet 340. Accordingly, the second end 342b of the third terminal pattern 342 is exposed to the first side surface of the filter stack 110, and connected to the second external electrode 130.

The fourth terminal pattern 344 is placed on the upper surface of the eighth sheet 340 so as to be spaced apart from the third terminal pattern 342. A first end 344a of the fourth terminal pattern 344 is connected to the first end 332a of the sixth coil pattern 332 through a via hole. A first end 344a of the fourth terminal pattern 344 is disposed adjacent to the center of the eighth sheet 340. The first end 344a of the fourth terminal pattern 344 is spaced apart from the first end 342a of the third terminal pattern 342 by a predetermined distance.

A second end 344b of the fourth terminal pattern 344 is disposed to be aligned with the first side of the eighth sheet 344. Accordingly, the second end 344b of the fourth terminal pattern 344 is spaced apart from the second end 342b of the third terminal pattern 342 by a predetermined distance, and is exposed to the first side surface of the filter stack 110 to be connected to the first external electrode 120 along with the second end 212b of the first terminal pattern 212.

The first stack 200 and the second stack 300 form a coil stack 400 that includes coils forming three channels.

The coil stack 400 is configured such that the first coil pattern 222, the second coil pattern 232, the third coil pattern 242, the fourth coil pattern 312, the fifth coil pattern 322, and the sixth coil pattern 332 are sequentially stacked.

Here, the first coil pattern 222 and the sixth coil pattern 332 form a first coil, which is a series inductor constituting the first channel. The second coil pattern 232 and the third coil pattern 242 form a second coil, which is a series inductor constituting the second channel. The fourth coil pattern 312 and the fifth coil pattern 322 form a third coil, which is a series inductor constituting the third channel.

Thus, the coil stack 400 forms a stack in which a coil pattern of the first channel, a coil pattern of the second channel, a coil pattern of the second channel, a coil pattern of the third channel, a coil pattern of the third channel, and a coil pattern of the first channel are sequentially disposed (stacked).

Accordingly, in the multilayer common mode filter 100 according to an embodiment of the present disclosure, a distance (spacing) between the coil patterns forming each channel may be kept constant, thereby enabling resistance and inductance of the coil patterns forming each channel to remain uniform.

Furthermore, the multilayer common mode filter 100 according to an embodiment of the present disclosure may minimize changes in inductance characteristics and common mode attenuation characteristics of the coil patterns by placing the terminal patterns for connection with the external electrodes in uppermost and lowermost portions of the coil stack 400. In the case where the terminal patterns are disposed in only one of the uppermost or lowermost portions, the inductance characteristics of each channel change, or the inductance characteristics of each coil pattern change, resulting in changes in the common mode attenuation characteristics.

In the multilayer common mode filter 100 according to an embodiment of the present disclosure, the terminal patterns are disposed in the uppermost and lowermost portions of the coil stack 400, the second coil pattern 232 and the third coil pattern 242 of the second channel are disposed between the first coil pattern 222 and the sixth coil pattern 332 of the first channel, and the fourth coil pattern 312 and the fifth coil pattern 322 of the third channel are disposed between the third coil pattern 242 and the sixth coil pattern 332. As a result, the number of via holes required for connecting the coil patterns may be minimized. The multilayer common mode filter 100 according to an embodiment of the present disclosure has two or fewer via holes formed in each sheet.

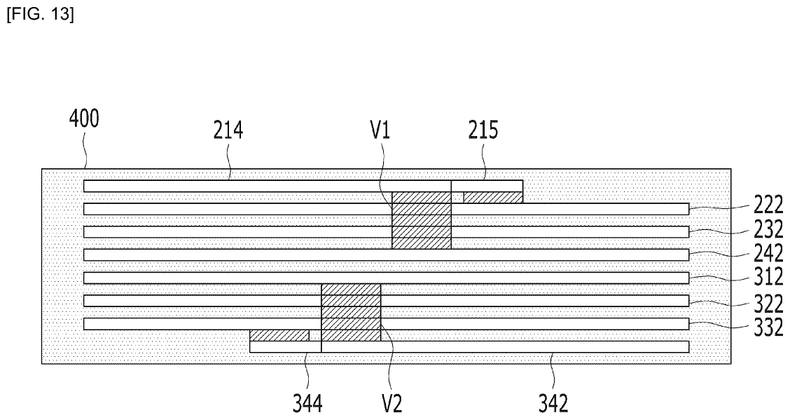

Referring to FIG. 13, the first coil pattern 222 and the sixth coil pattern 332 are respectively disposed in the upper and lower portions of the filter stack 110, thus forming the first channel. The second coil pattern 232 and the third coil pattern 242 are disposed (stacked) parallel to each other between the first coil pattern 222 and the sixth coil pattern 332, thus forming the second channel. The fourth coil pattern 312 and the fifth coil pattern 322 are disposed (stacked) parallel to each other between the third coil pattern 242 and the sixth coil pattern 332, thus forming the third channel.

Accordingly, the multilayer common mode filter 100 according to an embodiment of the present disclosure may be configured such that distances (spacing) between the first channel and the second channel, the second channel and the third channel, and the third channel and the first channel are maintained constant.

In addition, the multilayer common mode filter 100 according to an embodiment of the present disclosure can minimize changes in the inductance characteristics of the coil patterns by maintaining the constant distances (spacing) between the channels.

Furthermore, in the multilayer common mode filter 100 according to an embodiment of the present disclosure, since the terminal patterns that connect the coil patterns to the external electrodes are disposed in the uppermost and lowermost portions of the filter stack 110, the distances between the coil patterns and the terminal patterns can be made identical for all channels, thereby ensuring uniform resistance and inductance of the coil patterns that form each channel.

Additionally, the multilayer common mode filter 100 according to an embodiment of the present disclosure may enhance magnetic coupling (i.e., electromagnetic coupling) among the first to third coils and minimize the degradation of a differential signal.

The third stack 500 is disposed under the second stack 300. The third stack 500 is formed by stacking a plurality of sheets on which metal patterns are formed.

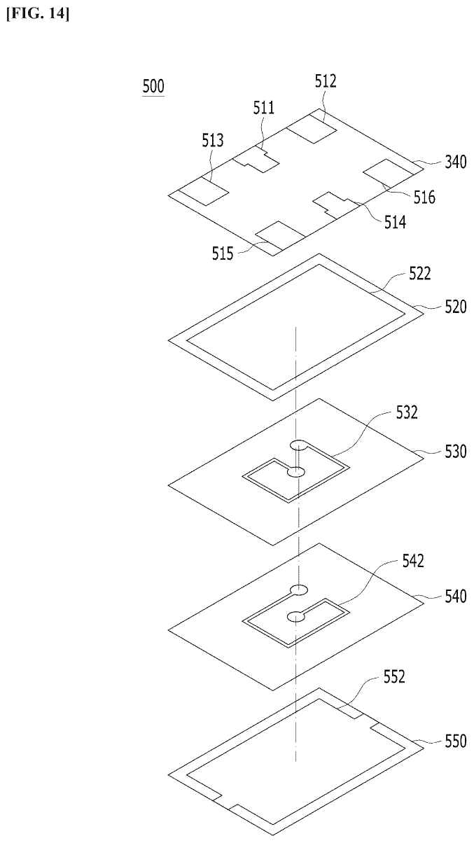

For example, referring to FIG. 14, the third stack 500 includes a ninth sheet 510, a tenth sheet 520 disposed under the ninth sheet 510, an eleventh sheet 530 disposed under the tenth sheet 520, a twelfth sheet 540 disposed under the eleventh sheet 530, and a thirteenth sheet 510 disposed under the twelfth sheet 540. Metal patterns 411 to 416 and 422 for forming capacitance are formed in the ninth sheet 510 and the tenth sheet 520. Metal pattern 432 and 442 for forming inductance are formed in the eleventh sheet 530 and the twelfth sheet 540. A metal pattern 452 for forming a ground is formed in the thirteenth sheet 510.

The ninth sheet 510 is disposed under the eighth sheet 340. A plurality of capacitor patterns are placed on an upper surface of the ninth sheet 510. The capacitor patterns may be configured as multiple patterns disposed on an input terminal and an output terminal of the multilayer common mode filter 100.

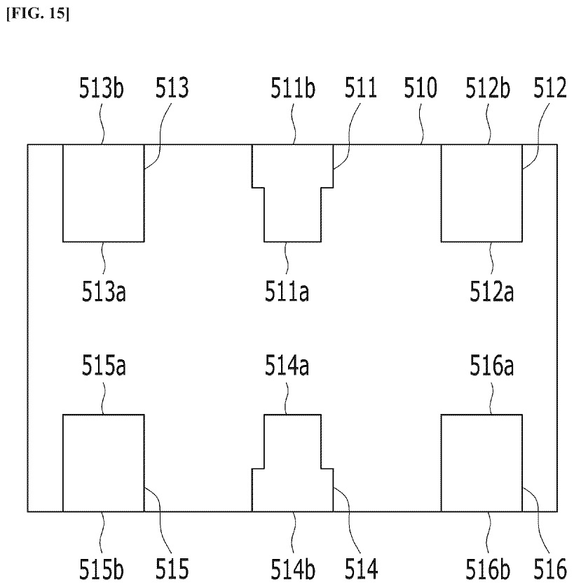

For example, referring to FIG. 15, the capacitor patterns include a first capacitor pattern 511, a second capacitor pattern 512, a third capacitor pattern 513, a fourth capacitor pattern 514, a fifth capacitor pattern 515, and a sixth capacitor pattern 516.

The first capacitor pattern 511 is placed on the upper surface of the ninth sheet 510.

A first end 511a of the first capacitor pattern 511 is disposed adjacent to a center of the ninth sheet 510.

A second end 511b of the first capacitor pattern 511 is disposed to be aligned with a first side of the ninth sheet 510. The first capacitor pattern 511 is exposed to the first side surface of the filter stack 110, and connected to the first external electrode 120.

The second capacitor pattern 512 is placed on the upper surface of the ninth sheet 510 so as to be spaced apart from the first capacitor pattern 511. The second capacitor pattern 512 is spaced apart from the first capacitor pattern 511, and is disposed to be biased toward a fourth side of the ninth sheet 510.

A first end 512a of the second capacitor pattern 512 is disposed adjacent to the center of the ninth sheet 510. A second end 512b of the second capacitor pattern 512 is disposed to be aligned with the first side of the ninth sheet 510. The second capacitor pattern 512 is exposed to the first side surface of the filter stack 110, and connected to the second external electrode 130.

The third capacitor pattern 513 is placed on the upper surface of the ninth sheet 510. The third capacitor pattern 513 is spaced apart from the first capacitor pattern 511 and the second capacitor pattern 512, and is disposed to be biased toward a third side of the ninth sheet 510. The third capacitor pattern 513 is disposed opposite to the second capacitor 512 with the first capacitor pattern 511 interposed therebetween.

A first end 513a of the third capacitor pattern 513 is disposed adjacent to the center of the ninth sheet 510. A second end 513b of the third capacitor pattern 513 is disposed to be aligned with the first side of the ninth sheet 510. The third capacitor pattern 513 is exposed to the first side surface of the filter stack 110, and connected to the third external electrode 140.

The fourth capacitor pattern 514 is placed on the upper surface of the ninth sheet 510.

A first end 514a of the fourth capacitor pattern 514 is disposed adjacent to the center of the ninth sheet 510. The first end 514a of the fourth capacitor pattern 514 faces the first end 511a of the first capacitor pattern 511.

A second end 514b of the fourth capacitor pattern 514 is disposed to be aligned with a second side of the ninth sheet 510. The fourth capacitor pattern 514 is exposed to the second side surface of the filter stack 110, and connected to the fourth external electrode 150.

The fifth capacitor pattern 515 is placed on the upper surface of the ninth sheet 510. The fifth capacitor pattern 515 is spaced apart from the fourth capacitor pattern 514, and is disposed to be biased toward the third side of the ninth sheet 510.

A first end 515a of the fifth capacitor pattern 515 is disposed adjacent to the center of the ninth sheet 510. The first end 515a of the fifth capacitor pattern 515 faces the first end 513a of the third capacitor pattern 513.

A second end 515b of the fifth capacitor pattern 515 is disposed to be aligned with the second side of the ninth sheet 510. The fifth capacitor pattern 515 is exposed to the second side surface of the filter stack 110, and connected to the fifth external electrode 160.

The sixth capacitor pattern 516 is placed on the upper surface of the ninth sheet 510. The sixth capacitor pattern 516 is spaced apart from the fourth capacitor pattern 514 and the fifth capacitor pattern 515, and is disposed to be biased toward the fourth side of the ninth sheet 510. The sixth capacitor pattern 516 is disposed opposite to the fifth capacitor pattern 515 with the fourth capacitor pattern 514 interposed therebetween.

A first end 516a of the sixth capacitor pattern 516 is disposed adjacent to the center of the ninth sheet 510. The first end 516a of the sixth capacitor pattern 516 faces the first end 512a of the second capacitor pattern 512.

A second end 516b of the sixth capacitor pattern 516 is disposed to be aligned with the second side of the ninth sheet 510. The sixth capacitor pattern 516 is exposed to the second side surface of the filter stack 110, and connected to the sixth external electrode 170.

It is assumed that the first to third external electrodes 120 to 140 disposed on the first side surface of the filter stack 110 serve as an input terminal of the multilayer common mode filter 100, and the third to sixth external electrodes 140 to 170 disposed on the second side surface of the filter stack 110 serve as an output terminal of the multilayer common mode filter 100.

The first to third capacitor patterns 511 to 513 are disposed on the first side surface of the filter stack 110 and are connected in a one-to-one manner to the first to third external electrodes 120 to 140, respectively. The fourth to sixth capacitor patterns 514 to 516 are disposed on the second side surface of the filter stack 110 and are connected in a one-to-one manner to the fourth to fifth external electrodes 150 to 160, respectively.

The filter stack 110 may include the ninth sheet 510 in which first to third capacitor patterns 511 to 513 connected to the input terminal are formed for adjusting and controlling capacitance characteristics, or the ninth sheet 510 in which fourth to sixth capacitor patterns 514 to 516 connected to the output terminal are formed.

The tenth sheet 520 is disposed under the ninth sheet 510. A floating pattern 522 for forming capacitance, along with the capacitor patterns of the ninth sheet 510, is placed on an upper surface of the tenth sheet 520.

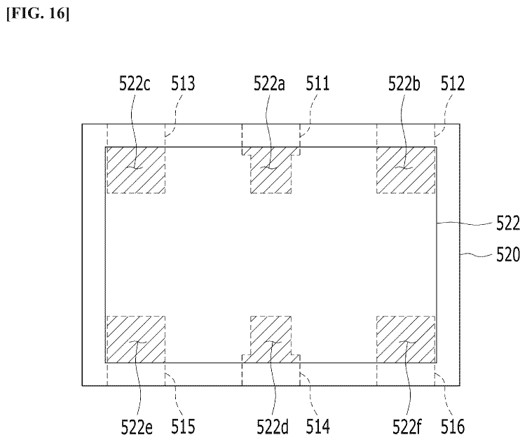

Referring to FIG. 16, the floating pattern 522 is formed in a plate shape, and placed on the upper surface of the tenth sheet 520. The floating pattern 522 has a smaller area than the tenth sheet 520, and is disposed such that an outer periphery of the floating pattern 522 is spaced apart from four sides of the tenth sheet 520. The area of the floating pattern 522 is larger than the areas of a first inductor pattern 532 and a second inductor pattern 542, which will be described later, and is formed to be 90% or less of the area of the tenth sheet 520.

The floating pattern 522 overlaps the capacitor patterns of the ninth sheet 510 to form an overlapping region, where capacitance is formed.

The floating pattern 522 forms a first overlapping region 522a with the first capacitor pattern 511, and forms a first capacitance in the first overlapping region 522a. The floating pattern 522 forms a second overlapping region 522b with the second capacitor pattern 512, and forms a second capacitance in the second overlapping region 522b. The floating pattern 522 forms a third overlapping region 522c with the third capacitor pattern 513, and forms a third capacitance in the third overlapping region 522c. The floating pattern 522 forms a fourth overlapping region 522d with the fourth capacitor pattern 514, and forms a fourth capacitance in the fourth overlapping region 522d. The floating pattern 522 forms a fifth overlapping region 522e with the fifth capacitor pattern 515, and forms a fifth capacitance in the fifth overlapping region 522e. The floating pattern 522 forms a sixth overlapping region 522f with the sixth capacitor pattern 516, and forms a sixth capacitance in the sixth overlapping region 522f.

As such, the floating pattern 522 forms capacitance with the capacitor patterns. Accordingly, the multilayer common mode filter 100 can expand the attenuation band by forming an additional notch in the common mode attenuation characteristics. That is, the multilayer common mode filter 100 can realize broadband characteristics by forming an additional pole due to the floating pattern 522 and the capacitor patterns, along with the pole formed by the coil patterns of the filter stack 110.

The eleventh sheet 530 is disposed under the tenth sheet 520. The first inductor pattern 532 is placed on an upper surface of the eleventh sheet 530.

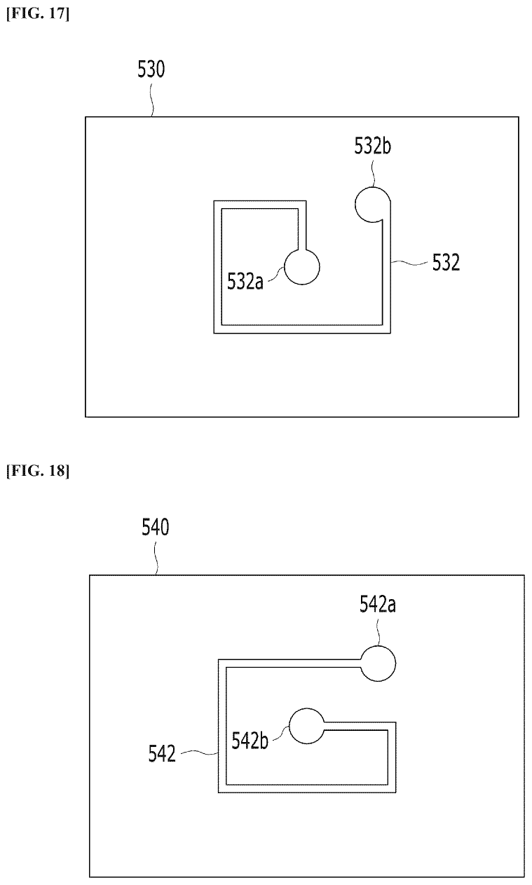

For example, referring to FIG. 17, the first inductor pattern 532 is wound on the upper surface of the eleventh sheet 530, thus forming a seventh loop. The first inductor pattern 532 is wound around a virtual winding axis passing through a center of the eleventh sheet 530 to form the seventh loop.

A first end 532a of the first inductor pattern 532 is disposed in an inner peripheral region of the seventh loop, and positioned at a center of the eleventh sheet 530. The first end 532a of the first inductor pattern 532 is connected to the floating pattern 522 of the tenth sheet through a via hole.

A second end 532b of the first inductor pattern 532 is disposed in an outer peripheral region of the seventh loop.

The twelfth sheet 540 is disposed under the eleventh sheet 530. The second inductor pattern 542 is placed on an upper surface of the twelfth sheet 540.

For example, referring to FIG. 18, the second inductor pattern 542 is wound on the upper surface of the twelfth sheet 540, thus forming an eighth loop. The second inductor pattern 542 is wound around a virtual winding axis passing through a center of the twelfth sheet 540 to form the eighth loop.

A first end 542a of the second inductor pattern 542 is disposed in an inner peripheral region of the eighth loop, and positioned at a center of the twelfth sheet 540. The first end 542a of the second inductor pattern 542 is connected to the ground pattern 552 of the thirteenth sheet 510 through a via hole passing through the twelfth sheet 540.

A second end 542b of the second inductor pattern 542 is disposed in an outer peripheral region of the eighth loop. The first end 542b of the second inductor pattern 542 is connected to the first inductor pattern 532 of the eleventh sheet 530 through a via hole. The second end 542b of the second inductor pattern 542 is connected to the second end 532b of the first inductor pattern 532 through a via hole.

As the second end 532b of the first inductor pattern 532 and the second end 542b of the second inductor pattern 542 are connected through the via hole, the first inductor pattern 532 and the second inductor pattern 542 constitute a parallel common inductor that forms a predetermined inductance.

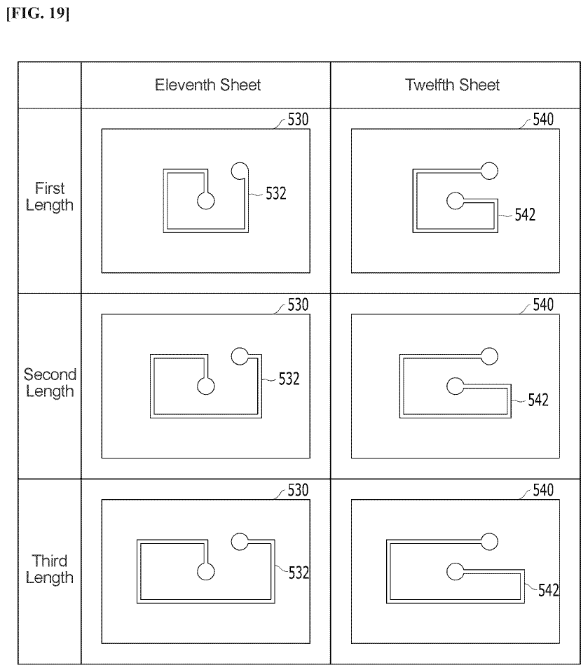

Referring to FIG. 19, the lengths (areas) of the first inductor pattern 532 and the second inductor pattern 542 may vary depending on a required secondary resonant frequency.

As the lengths of the first inductor pattern 532 and the second inductor pattern 542 increase, the inductance value increases, and the secondary resonant frequency shifts to a lower frequency. As the lengths of the first inductor pattern 532 and the second inductor pattern 542 decrease, the inductance value decreases, and the secondary resonant frequency shifts to a higher frequency.

Accordingly, the lengths of the first inductor pattern 532 and the second inductor pattern 542 are determined based on the required secondary resonant frequency. The first inductor pattern 532 and the second inductor pattern 542 may be formed with the same length or with different lengths.

The thirteenth sheet 510 is disposed under the twelfth sheet 540. The ground pattern 552 is formed in the thirteenth sheet 510.

The ground pattern 552 is connected to the inductor patterns 532 and 542 and reduces the influence of stray capacitance formed between the multilayer common mode filter 100 and a printed circuit board.

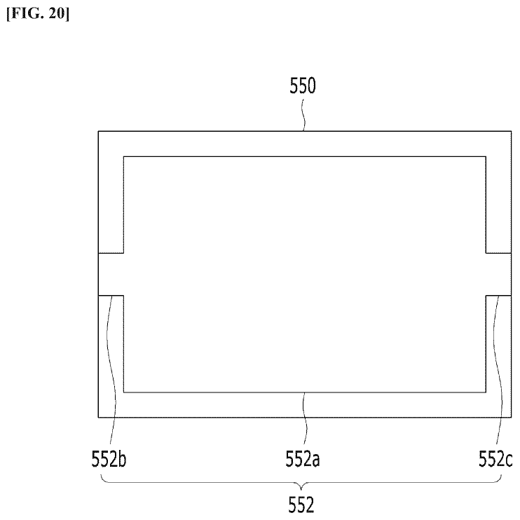

For example, referring to FIG. 20, the ground pattern 552 is formed on an upper surface of the thirteenth sheet 510. The ground pattern 552 includes a first ground pattern 552a, a second ground pattern 552b, and a third ground pattern 552c.

The first ground pattern 552a is formed in a plate shape, and positioned at a center of the upper surface of the thirteenth sheet 510. The first ground pattern 552a has a smaller area than the thirteenth sheet 510, and is disposed such that an outer periphery of the first ground pattern 552a is spaced apart from four sides of the thirteenth sheet 510. The first ground pattern 552a is connected to the first end 542a of the second inductor pattern 542 through a via hole passing through the twelfth sheet 540.

The second ground pattern 552b extends from a third side of the first ground pattern 552a and is disposed to be aligned with a third side of the thirteenth sheet 510. A first end of the second ground pattern 552b is connected to the third side of the first ground pattern 552a. A second end of the second ground pattern 552b is disposed to be aligned with the third side of the thirteenth sheet 510, and is connected to the seventh external electrode 180.

The third ground pattern 552c extends from a fourth side of the first ground pattern 552a and is disposed to be aligned with a fourth side of the thirteenth sheet 510. A first end of the third ground pattern 552c is connected to the fourth side of the first ground pattern 552a. A second end of the third ground pattern 552c is disposed to be aligned with the fourth side of the thirteenth sheet 510, and is connected to the eighth external electrode 190.

Accordingly, the ground pattern 552 is exposed to third and fourth side surfaces of the filter stack 110, thus forming a ground connected to the seventh external electrode 180 and the eighth external electrode 190.

The first external electrode 120 is placed on the first side surface of the filter stack 110. Opposite ends of the first external electrode 120 may be formed to extend to upper and lower surfaces of the filter stack 110.

The first external electrode 120 is connected to the first terminal pattern 212, the fourth terminal pattern 344, and the first capacitor pattern 511 that are exposed to the first side surface of the filter stack 110. In this case, the first external electrode 120 is connected to the second end 212b of the first terminal pattern 212, the second end 344b of the fourth terminal pattern 344, and the second end 511b of the first capacitor pattern 511.

The second external electrode 130 is placed on the first side surface of the filter stack 110. The second external electrode 130 is disposed to be biased toward the fourth side surface of the filter stack 110, and is spaced apart from the first external electrode 120. Opposite ends of the second external electrode 130 may be formed to extend to the upper and lower surfaces of the filter stack 110.

The second external electrode 130 is connected to the third terminal pattern 342 and the second capacitor pattern 512 that are exposed to the first side surface of the filter stack 110. The second external electrode 130 is connected to the second end 342b of the third terminal pattern 342 and the second end 512b of the second capacitor pattern 512.

The third external electrode 140 is placed on the first side surface of the filter stack 110. The third external electrode 140 is disposed to be biased toward the third side surface of the filter stack 110, and is spaced apart from the first external electrode 120. The third external electrode 140 is opposite to the second external electrode 130 with the first external electrode 120 interposed therebetween. Opposite ends of the third external electrode 140 may be formed to extend to the upper and lower surfaces of the filter stack 110.

The third external electrode 140 is connected to the second terminal pattern 214 and the third capacitor pattern 513 that are exposed to the first side surface of the filter stack 110. The third external electrode 140 is connected to the second end 214b of the second terminal pattern 214 and the second end 513b of the third capacitor pattern 513.

The fourth external electrode 150 is placed on the second side surface of the filter stack 110. The fourth external electrode 150 is opposite to the first external electrode 120 with the filter stack 110 interposed therebetween, and is disposed to face the first external electrode 120. Opposite ends of the fourth external electrode 150 may be formed to extend to the upper and lower surfaces of the filter stack 110.

The fourth external electrode 150 is connected to the first coil pattern 222, the sixth coil pattern 332, and the fourth capacitor pattern 514 that are exposed to the second side surface of the filter stack 110. The fourth external electrode 150 is connected to the second end 222b of the first coil pattern 222, the second end 332b of the sixth coil pattern 332, and the second end 514b of the fourth capacitor pattern 514.

The fifth external electrode 160 is placed on the second side surface of the filter stack 110. The fifth external electrode 160 is opposite to the third external electrode 140 with the filter stack 110 interposed therebetween, and is disposed to face the third external electrode 140. The fifth external electrode 160 is disposed to be biased toward the third side surface of the filter stack 110, and is spaced apart from the fourth external electrode 150. Opposite ends of the fifth external electrode 160 may be formed to extend to the upper and lower surfaces of the filter stack 110.

The fifth external electrode 160 is connected to the second coil pattern 232, the third coil pattern 242, and the fifth capacitor pattern 515 that are exposed to the second side surface of the filter stack 110. The fifth external electrode 160 is connected to the second end 232b of the second coil pattern 232, the second end 242b of the third coil pattern 242, and the second end 515b of the fifth capacitor pattern 515.

The sixth external electrode 170 is placed on the second side surface of the filter stack 110. The sixth external electrode 170 is opposite to the second external electrode 130 with the filter stack 110 interposed therebetween, and is disposed to face the second external electrode 130. The sixth external electrode 170 is disposed to be biased toward the fourth side surface of the filter stack 110, and is spaced apart from the fourth external electrode 150. The sixth external electrode 170 is opposite to the fifth external electrode 160 with the fourth external electrode 150 interposed therebetween. Opposite ends of the sixth external electrode 170 may be formed to extend to the upper and lower surfaces of the filter stack 110.

The sixth external electrode 170 is connected to the fourth coil pattern 312, the fifth coil pattern 322, and the sixth capacitor pattern 516 that are exposed to the second side surface of the filter stack 110. The sixth external electrode 170 is connected to the second end 312b of the fourth coil pattern 312, the second end 322b of the fifth coil pattern 322, and the second end 516b of the sixth capacitor pattern 516.

The seventh external electrode 180 is placed on the third side surface of the filter stack 110. The seventh external electrode 180 is connected to the ground pattern 552 exposed to the third side surface of the filter stack 110. The seventh external electrode 180 is connected to the second end of the second ground pattern 552b exposed to the third side surface of the filter stack 110. Opposite ends of the seventh external electrode 180 may be formed to extend to the upper and lower surfaces of the filter stack 110.

The eighth external electrode 190 is placed on the fourth side surface of the filter stack 110. The eighth external electrode 190 is opposite to the seventh external electrode 180 with the filter stack 110 interposed therebetween. The eighth external electrode 190 is connected to the ground pattern 552 exposed to the third side surface of the filter stack 110. The eighth external electrode 190 is connected to the second end of the third ground pattern 552c exposed to the fourth side surface of the filter stack 110. Opposite ends of the eighth external electrode 190 may be formed to extend to the upper and lower surfaces of the filter stack 110.

The first external electrode 120 and the fourth external electrode 150 function as an input terminal and an output terminal of the first channel, which is formed by the first coil pattern 222 and the sixth coil pattern 332. The third external electrode 140 and the fifth external electrode 160 function as an input terminal and an output terminal of the second channel, which is formed by the second coil pattern 232 and the third coil pattern 242. The second external electrode 130 and the sixth external electrode 170 function as an input terminal and an output terminal of the third channel, which is formed by the fourth coil pattern 312 and the fifth coil pattern 322. The seventh external electrode 180 and the eighth external electrode 190 are connected to the ground pattern 552, thus functioning as a ground terminal.

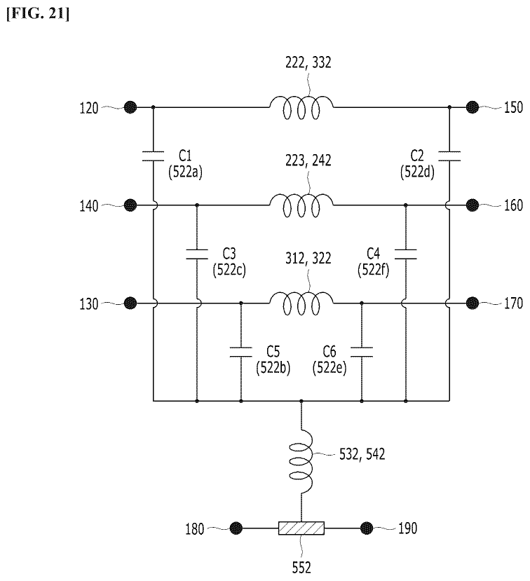

Referring to FIG. 21 illustrating an equivalent circuit of the multilayer common mode filter 100 according to an embodiment of the present disclosure, capacitance is formed between the first coil and the second coil, between the second coil and the third coil, and between the first coil and the third coil.

The filter stack 110 is formed in such a way that the coil stack 400 is formed by stacking the first stack 20 and the second stack 300 on which the coil patterns are formed, and the third stack 500, which includes the capacitor patterns, the floating pattern 522, and the inductor patterns 532 and 542, is placed under the coil stack 400. Accordingly, the capacitor patterns connected between the coils of the respective channel and the external electrodes are interconnected, and a coupling effect is induced between the capacitor patterns and the floating pattern 522. As a result, additional capacitances C1 to C6 are formed between the coils of the respective channels and the external electrodes due to the capacitor patterns and the floating pattern 522.

Consequently, the multilayer common mode filter 100 according to an embodiment of the present disclosure can have increased capacitance without the need to add an electrode layer including a coil pattern or increase the area of the coil patterns, thereby achieving greater capacitance than a prior multilayer common mode filter 10 while maintaining the same size.

Furthermore, in the multilayer common mode filter 100 according to an embodiment of the present disclosure, as additional capacitance is formed by the capacitor pattern and the floating pattern 522, an additional notch can be formed in the common mode attenuation characteristics, thereby expanding the attenuation band.

The first inductor pattern 532 and the second inductor pattern 542 form a single inductor. Opposite ends of the inductor 532 and 542 formed by the first inductor pattern 532 and the second inductor pattern 542 are respectively connected to the floating pattern 522 and the ground pattern 552, and form a short path circuit between the floating pattern 522 and the ground pattern 552.

The inductance of the inductor 532 and 542, which is formed by the first inductor pattern 532 and the second inductor pattern 542, can be defined by the lengths of the first inductor pattern 532 and the second inductor pattern 542. The inductance of the inductor 532 and 542, which is formed by the first inductor pattern 532 and the second inductor pattern 542, is a dominant factor in adjusting and controlling the secondary resonant frequency of the multilayer common mode filter 100.

A primary resonant frequency is determined by the capacitance formed between the first coil, the second coil, and the third coil. The secondary resonant frequency is determined by the capacitor patterns 511 to 516, the floating pattern 522, and the inductor patterns 532 and 542.

Here, the inductor patterns 532 and 542 have a relatively higher inductance value compared to the capacitance formed between the capacitor patterns 511 to 516 and the floating pattern 522, thus serving as a dominant factor in determining the secondary resonant frequency.

The inductor patterns 532 and 542 have, within the same area, a value adjustment range allowing the secondary resonant frequency to be adjusted to various values, and can improve design flexibility due to having a smaller area compared to the capacitor patterns 511 to 516. The capacitor patterns 511 to 516 and the floating pattern 522 form a relatively small capacitance compared to the inductor patterns 532 and 542, thereby reducing loss during signal transmission.

As such, the inductor patterns 532 and 542 serve as the dominant factor in determining the secondary resonant frequency and can reduce the influence of parasitic inductance (parasitic L) that varies depending on the mounting orientation of a chip, thereby preventing characteristic deviations due to the mounting orientation.

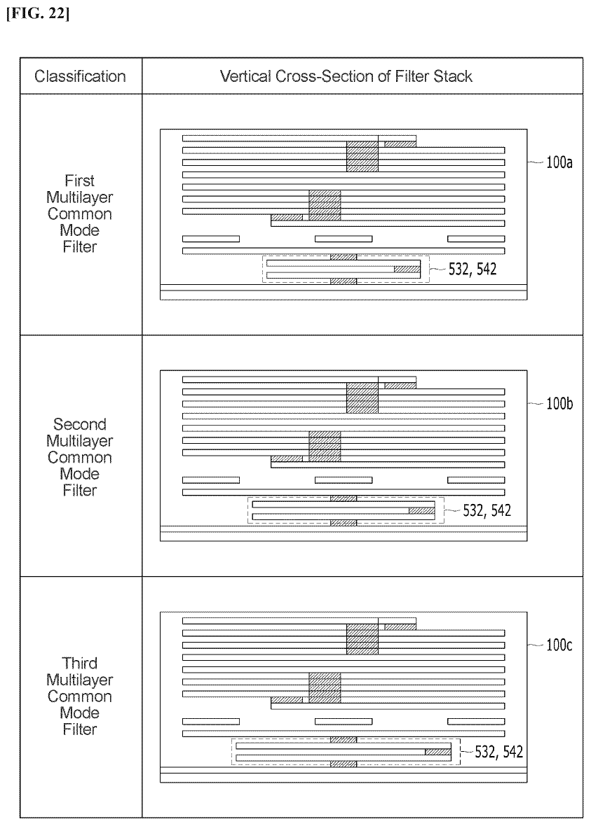

Referring to FIG. 22, it is assumed that a first multilayer common mode filter 100a has the first inductor pattern 532 and the second inductor pattern 542 that are formed with a first length, a second multilayer common mode filter 100b has the first inductor pattern 532 and the second inductor pattern 542 that are formed with a second length, and a third multilayer common mode filter 100c has the first inductor pattern 532 and the second inductor pattern 542 that are formed with a third length. The first length is shorter than the second length, and the second length is shorter than the third length.

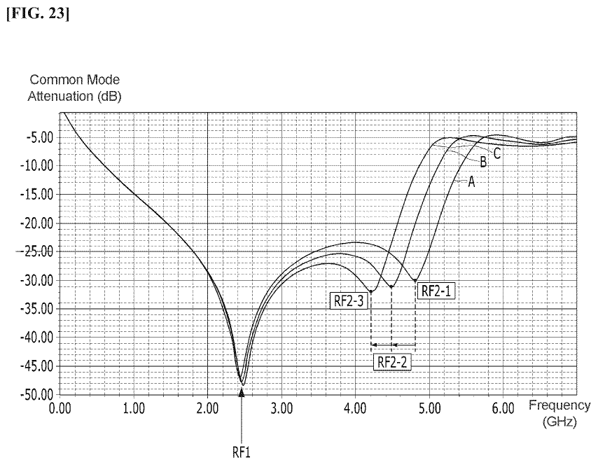

Referring to FIG. 23, based on a common mode, the first multilayer common mode filter 100a (A), the second multilayer common mode filter 100b (B), and the third multilayer common mode filter 100c (C) form first resonant frequencies RF1 at approximately 2.45 GHz. The first resonant frequencies RF1 of the first to third multilayer common mode filters 100a (A) to 100c (C) can be regarded as the same within the margin of error.

On the other hand, the first to third multilayer common mode filters 100a to 100c form different second resonant frequencies RF2-1 to RF2-3 in the common mode. In other words, the first multilayer common mode filter 100a (refer to A) forms the second resonant frequency RF2-1 at approximately 4.8 GHz, the second multilayer common mode filter 100b (refer to B) forms the second resonant frequency RF2-2 at approximately 4.5 GHz, and the third multilayer common mode filter 100c (refer to C) forms the second resonant frequency RF2-3 at approximately 4.2 GHz.

That is, as the lengths of the inductor patterns (i.e., the first inductor pattern 532 and the second inductor pattern 542) increase, the inductance increase, and the second resonant frequency of the multilayer common mode filter 100 shifts toward a lower frequency. As the lengths of the inductor patterns (i.e., the first inductor pattern 532 and the second inductor pattern 542) decrease, the inductance decreases, and the second resonant frequency of the multilayer common mode filter 100 shifts toward a higher frequency.

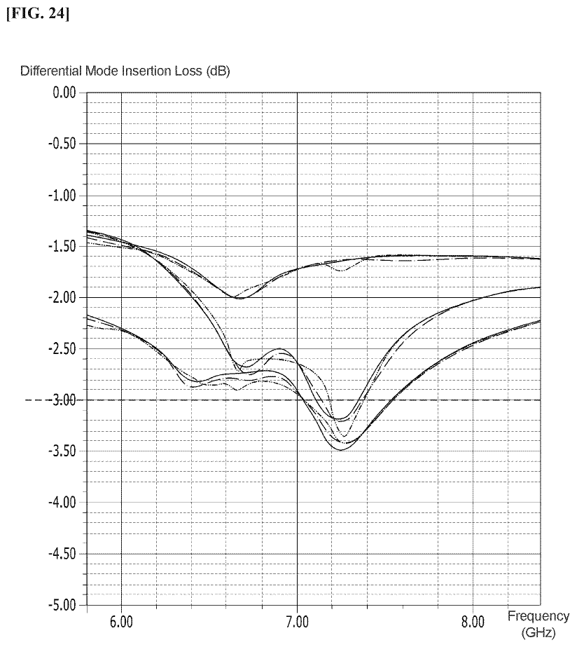

Referring to FIG. 24, based on a differential mode, the first to third multilayer common mode filters 100a to 100c exhibit cutoff at approximately 7.1 GHz, 7.2 GHz, 7.37 GHz, and 7.53 GHz. The cutoff frequencies of the first to third multilayer common mode filters 100a to 100c can be regarded as the same within the margin of error.

Accordingly, it can be understood that the lengths of the inductor patterns 532 and 542 serve as a dominant factor in adjusting (controlling) the second resonant frequency of the multilayer common mode filter 100. The second resonant frequency characteristics of the multilayer common mode filter 100 can be modified by adjusting the length of the first inductor pattern 532 and/or the length of the second inductor pattern 542.

Furthermore, in the multilayer common mode filter 100 according to an embodiment of the present disclosure, a short path circuit is formed by placing (arranging) the third stack 500, which includes the inductor patterns 532 and 542, under the coil stack 400, thereby allowing the second resonant frequency to be readily adjusted/controlled by adjusting the lengths of the inductor patterns 532 and 542.

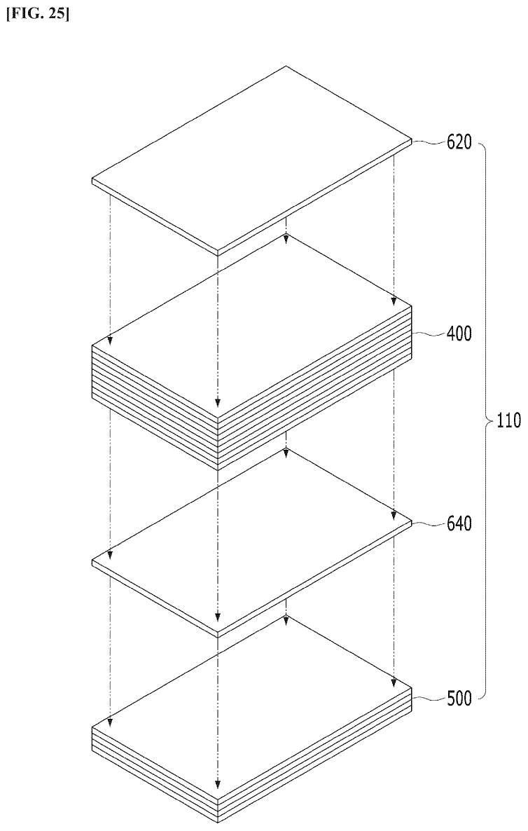

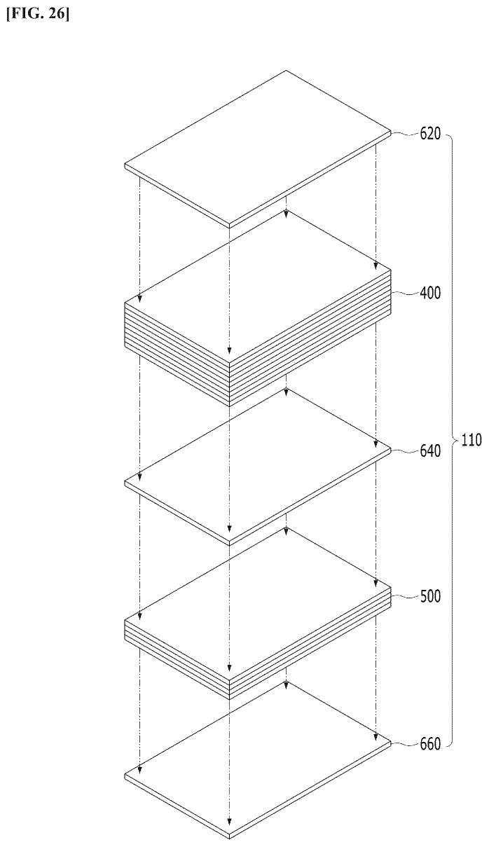

Referring to FIG. 25, the filter stack 110 may further include a first magnetic sheet 620 disposed on an upper portion of the first stack 200, and a second magnetic sheet 640 interposed between the second stack 300 and the third stack 500. Here, as an example, the first magnetic sheet 620 and the second magnetic sheet 640 are sheets formed of magnetic material such as ferrite.

Referring to FIG. 26, the filter stack 110 may further include a third magnetic sheet 660 disposed under the third stack 500. Here, as an example, the third magnetic sheet 660 is a sheet formed of magnetic material such as ferrite. The ferrite may include Ni—Zn or Mn—Zn.

The third magnetic sheet 660 can increase parallel inductance induced by the inductor patterns 532 and 542. The addition of the third magnetic sheet 660 to the lowermost portion in the same multilayer structure enables the multilayer common mode filter 100 to have a lower secondary resonant frequency.

In the multilayer common mode filter 100 according to an embodiment of the present disclosure, the interval between the first resonant frequency and the second resonant frequency can be adjusted depending on the presence or absence of the third magnetic sheet 660, which is disposed in the lowermost portion of the filter stack 110. Here, placing the third magnetic sheet 660 can reduce the interval (or result in a narrower interval) between the first resonant frequency and the second resonant frequency in the multilayer common mode filter 100.

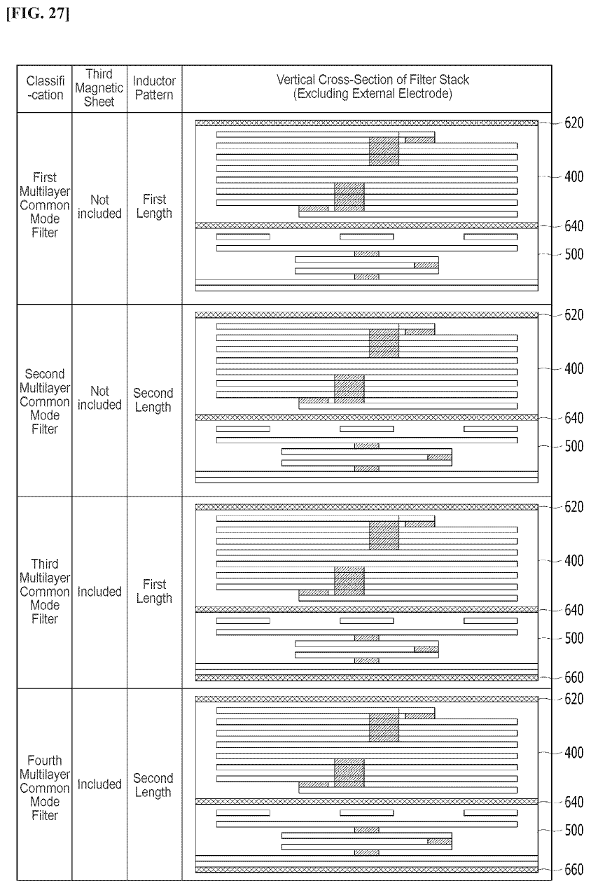

Referring to FIG. 27, a first multilayer common mode filter 100a does not include the third magnetic sheet 660, and the inductor patterns 532 and 542 are formed with a first length. A second multilayer common mode filter 100b does not include the third magnetic sheet 660, and the inductor patterns 532 and 542 are formed with a second length, which is longer than the first length. A third multilayer common mode filter 100c includes the third magnetic sheet 660, and the inductor patterns 532 and 542 are formed with the first length. A fourth multilayer common mode filter 100 includes the third magnetic sheet 660, and the inductor patterns 532 and 542 are formed with the second length, which is longer than the first length.

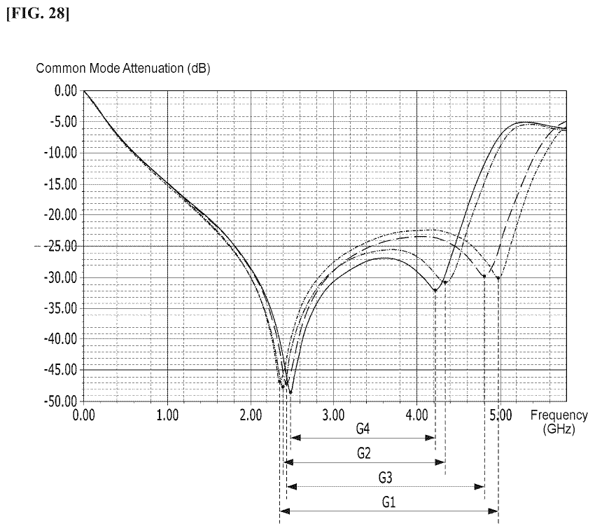

Referring to FIG. 28, the first multilayer common mode filter 100a has a first resonant frequency of approximately 2.35 GHz and a second resonant frequency of approximately 4.97 GHz. The second multilayer common mode filter 100b has a first resonant frequency of approximately 2.38 GHz and a second resonant frequency of approximately 4.37 GHz. The third multilayer common mode filter 100c has a first resonant frequency of approximately 2.45 GHz and a second resonant frequency of approximately 4.8 GHz. The fourth multilayer common mode filter 100 has a first resonant frequency of approximately 2.50 GHz and a second resonant frequency of approximately 4.21 GHz.

An interval G1 between the first resonant frequency and the second resonant frequency of the first multilayer common mode filter 100a is approximately 2.62 GHz. An interval G2 between the first resonant frequency and the second resonant frequency of the second multilayer common mode filter 100b is approximately 1.99 GHz. An interval G3 between the first resonant frequency and the second resonant frequency of the third multilayer common mode filter 100c is approximately 2.35 GHz. An interval G4 between the first resonant frequency and the second resonant frequency of the fourth multilayer common mode filter 100 is approximately 1.71 GHz.

Comparing the first multilayer common mode filter 100a and the third multilayer common mode filter 100c, which have the same length of inductor patterns 532 and 542, the interval G3 of the third multilayer common mode filter 100c, which includes the third magnetic sheet 660, decreases by approximately 0.27 GHz compared to the interval G1 of the first multilayer common mode filter 100a, which does not include the third magnetic sheet 660.

Comparing the second multilayer common mode filter 100b and the fourth multilayer common mode filter 100, which have the same length of inductor patterns 532 and 542, the interval G4 of the fourth multilayer common mode filter 100, which includes the third magnetic sheet 660, decreases by approximately 0.28 GHz compared to the interval G2 of the second multilayer common mode filter 100b, which does not include the third magnetic sheet 660.

Accordingly, in the multilayer common mode filter 100 according to an embodiment of the present disclosure, the interval between the first resonant frequency and the second resonant frequency can be adjusted (controlled) by using the third magnetic sheet 660, which is disposed in the lowermost portion of the filter stack 110.

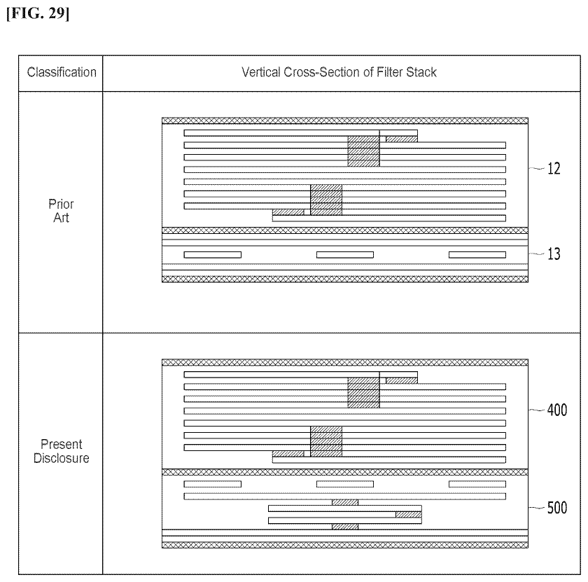

Referring to FIG. 29, unlike the prior multilayer common mode filter having a structure in which a coil stack 12 and a capacitor stack 13 are stacked (i.e., an LC filter structure), the multilayer common mode filter 100 according to an embodiment of the present disclosure has a structure in which the third stack 500, in which a capacitor and an inductor are stacked, is placed under the coil stack 400 (i.e., an LPF filter structure). As a result, the multilayer common mode filter 100 according to an embodiment of the present disclosure exhibits improved attenuation characteristics in the common mode and enhanced characteristics in terms of insertion loss and cutoff in the differential mode compared to the prior multilayer common mode filter 10.

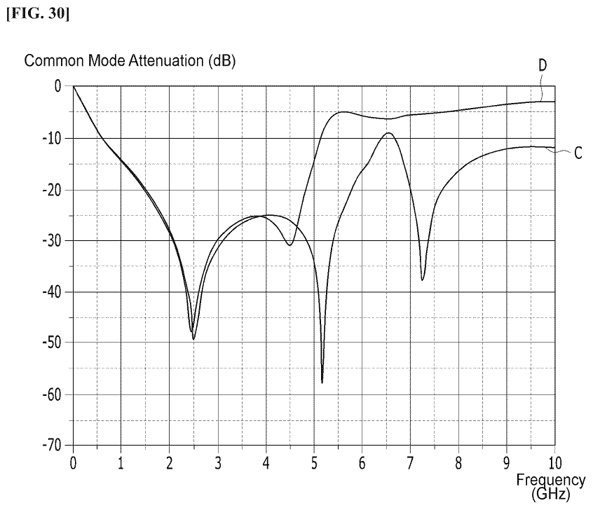

Referring to FIG. 30, the prior multilayer common mode filter (refer to C) forms three resonant frequencies, with a first resonant frequency formed at approximately 2.5 GHz, a second resonant frequency formed at approximately 5.2 GHz, and a third resonant frequency formed at approximately 7.3 GHz.

The multilayer common mode filter 100 (refer to D) according to an embodiment of the present disclosure forms two resonant frequencies, with a first resonant frequency formed at approximately 2.5 GHz and a second resonant frequency formed at approximately 5.5 GHz.

As such, the multilayer common mode filter 100 according to an embodiment of the present disclosure has attenuation performance concentrated only in the common mode attenuation band (i.e., a target band), indicating that the attenuation characteristics in the common mode are improved compared to the prior multilayer common mode filter 10.

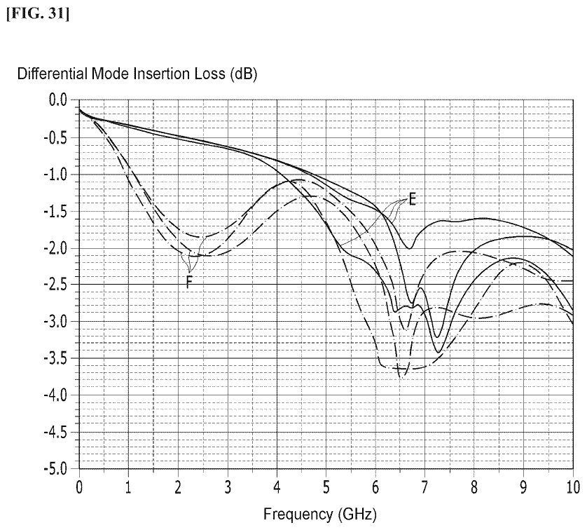

Referring to FIG. 31, the multilayer common mode filter 100 (refer to E) according to an embodiment of the present disclosure exhibits improved low-frequency cutoff characteristics and reduced ripple in the differential mode, compared to the prior multilayer common mode filter (refer to F).

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A multilayer common mode filter comprising:
a first stack provided with a first coil pattern, a second coil pattern, and a third coil pattern;
a second stack provided with a fourth coil pattern, a fifth coil pattern, and a sixth coil pattern, and disposed under the first stack; and
a third stack disposed under the second stack,
wherein the third stack comprises:
a plurality of capacitor patterns disposed under the second stack;
a floating pattern disposed under the plurality of capacitor patterns, and configured to form additional capacitance by overlapping the plurality of capacitor patterns;
a ground pattern disposed under the floating pattern; and
an inductor pattern disposed between the floating pattern and the ground pattern, and
wherein a first end of the inductor pattern is connected to the floating pattern, and a second end of the inductor pattern is connected to the ground pattern.

2. The multilayer common mode filter of claim 1,
wherein the first stack and the second stack form a coil stack,
wherein the coil stack is configured such that the first coil pattern, the second coil pattern, the third coil pattern, the fourth coil pattern, the fifth coil pattern, and the sixth coil pattern are sequentially stacked,
wherein the first coil pattern and the sixth coil pattern form a first coil that forms a first channel,
wherein the second coil pattern and the third coil pattern are interposed between the first coil pattern and the sixth coil pattern, and form a second coil that forms a second channel, and
wherein the fourth coil pattern and the fifth coil pattern are interposed between the third coil pattern and the sixth coil pattern, and form a third coil that forms a third channel.

3. The multilayer common mode filter of claim 1, wherein the first stack comprises:
a first sheet;
a first terminal pattern placed on a first surface of the first sheet;
a second terminal pattern placed on the first surface of the first sheet, and spaced apart from the first terminal pattern;
a second sheet disposed under the first sheet;
the first coil pattern forming a first loop wound on a first surface of the second sheet, the first coil pattern including a first end positioned in an inner peripheral region of the first loop and connected to the first terminal pattern through a via hole passing through the first sheet, and a second end positioned in an outer peripheral region of the first loop;
a third sheet disposed under the second sheet;
the second coil pattern forming a second loop wound on a first surface of the third sheet, the second coil pattern including a first end positioned in an inner peripheral region of the second loop and connected to the second terminal pattern through a via hole passing through the first sheet and the second sheet, and a second end positioned in an outer peripheral region of the second loop;
a fourth sheet disposed under the third sheet; and
the third coil pattern forming a third loop wound on a first surface of the fourth sheet, the third coil pattern including a first end positioned in an inner peripheral region of the third loop and connected to the second end of the second coil pattern through a via hole passing through the third sheet, and a second end positioned in an outer peripheral region of the third loop.

4. The multilayer common mode filter of claim 1, wherein the second stack comprises:
a fifth sheet;
the fourth coil pattern forming a fourth loop wound on a first surface of the fifth sheet, the fourth coil pattern including a first end positioned in an inner peripheral region of the fourth loop, and a second end positioned in an outer peripheral region of the fourth loop;
a sixth sheet disposed under the fifth sheet;
the fifth coil pattern forming a fifth loop wound on a first surface of the sixth sheet, the fifth coil pattern including a first end positioned in an inner peripheral region of the fifth loop and connected to the first end of the fourth coil pattern through a via hole passing through the fifth sheet, and a second end positioned in an outer peripheral region of the fifth loop;
a seventh sheet disposed under the sixth sheet;
the sixth coil pattern forming a sixth loop wound on a first surface of the seventh sheet, the sixth coil pattern including a first end positioned in an inner peripheral region of the sixth loop, and a second end positioned in an outer peripheral region of the sixth loop;
an eighth sheet disposed under the seventh sheet;
a third terminal pattern placed on the first surface of the seventh sheet, and including a first end connected to the first end of the fourth coil pattern and the first end of the fifth coil pattern through a via hole passing through the fifth sheet, the sixth sheet, and the seventh sheet; and
a fourth terminal pattern placed on the first surface of the seventh sheet and spaced apart from the third terminal pattern, the fourth terminal pattern including a first end connected to the first end of the sixth coil pattern through a via hole passing through the seventh sheet.

5. The multilayer common mode filter of claim 1, wherein the third stack comprises:
a ninth sheet;
a plurality of capacitor patterns placed on a first surface of the ninth sheet and spaced apart from each other;
a tenth sheet disposed under the ninth sheet; and
a floating pattern placed on a first surface of the tenth sheet, and forming a plurality of overlapping areas by overlapping the plurality of capacitor patterns, the floating pattern being configured to form additional capacitance in the plurality of overlapping regions.

6. The multilayer common mode filter of claim 5, wherein the third stack further comprises:
the ground pattern disposed under the tenth sheet; and
the inductor pattern interposed between the tenth sheet and the ground pattern, and including a first end connected to the floating pattern, and a second end connected to the ground pattern.

7. The multilayer common mode filter of claim 6,
wherein the third stack further comprises:
an eleventh sheet interposed between the tenth sheet and the ground pattern; and
a twelfth sheet interposed between the eleventh sheet and the ground pattern,
wherein the inductor pattern comprises:
a first inductor pattern placed on a first surface of the eleventh sheet, and including a first end connected to the floating pattern through a via hole passing through the tenth sheet, and a second end spaced apart from the first end; and
a second inductor pattern placed on a first surface of the twelfth sheet, and including a first end connected to the ground pattern, and a second end connected to the second end of the first inductor pattern through a via hole passing through the eleventh sheet.

8. The multilayer common mode filter of claim 1, further comprising
a first magnetic sheet disposed over the first stack; and
a second magnetic sheet interposed between the second stack and the third stack.

9. The multilayer common mode filter of claim 1, further comprising a third magnetic sheet disposed under the third stack.

10. The multilayer common mode filter of claim 1,
wherein a filter stack formed by stacking the first stack, the second stack, and the third stack has a first resonant frequency, and a second resonant frequency higher than the first resonant frequency, and
wherein the second resonant frequency shifts to a higher frequency as a length of the inductor pattern increases.

11. The multilayer common mode filter of claim 1,
wherein a filter stack formed by stacking the first stack, the second stack, and the third stack has a first resonant frequency, and a second resonant frequency higher than the first resonant frequency, and
wherein the second resonant frequency shifts to a lower frequency as a length of the inductor pattern decreases.

12. The multilayer common mode filter of claim 1,
wherein a filter stack formed by stacking the first stack, the second stack, and the third stack includes a first side surface, a second side surface opposite to the first side surface, a third side surface, and a fourth side surface opposite to the third side surface, the multilayer common mode filter further comprising:
a first external electrode disposed on the first side surface, and connected to a second end of a first terminal pattern, a second end of a fourth terminal pattern, and a second end of a first capacitor pattern that are exposed to the first side surface;
a second external electrode disposed on the first side surface, and connected to a second end of a third terminal pattern and a second end of a second capacitor pattern that are exposed to the first side surface;
a third external electrode disposed on the first side surface, and connected to a second end of a second terminal pattern and a second end of a third capacitor pattern that are exposed to the first side surface;
a fourth external electrode disposed on the second side surface, and connected to a second end of the first coil pattern, a second end of the sixth coil pattern, and a second end of a fourth capacitor pattern that are exposed to the second side surface;
a fifth external electrode disposed on the second side surface, and connected to a second end of the second coil pattern, a second end of the third coil pattern, and a second end of a fifth capacitor pattern that are exposed to the second side surface; and
a sixth external electrode disposed on the second side surface, and connected to a second end of the fourth coil pattern, a second end of the fifth coil pattern, and a second end of a sixth capacitor pattern that are exposed to the second side surface.

13. The multilayer common mode filter of claim 12, further comprising:
a seventh external electrode disposed on the third surface, and connected to a first end of a ground pattern that is exposed to the third side surface; and
an eighth external electrode disposed on the fourth side surface, and connected to a second end of the ground pattern that is exposed to the fourth side surface.
